(19) United States
(12) Patent Application Publication
(10) Pub. No.: US 2026/0051354 A1
(43) Pub. Date: Feb. 19, 2026

(54) MEMORY DEVICE THAT INCREASES SENSING MARGIN THROUGH CHARGE SHARING OPERATION AND SENSING METHOD THEREOF

(71) Applicant: SAMSUNG ELECTRONICS CO., LTD., Suwon-si (KR)

(72) Inventors: Jaehue Shin, Suwon-si (KR); Hyunkook Park, Suwon-si (KR); Ji-Sang Lee, Suwon-si (KR)

(21) Appl. No.: 19/224,648

(22) Filed: May 30, 2025

(30) Foreign Application Priority Data
Aug. 16, 2024 (KR) 10-2024-0109970

(51) Int. Cl. G11C 16/26; G11C 16/04; G11C 16/24; G11C 16/30

(52) U.S. Cl. CPC G11C 16/26; G11C 16/0483; G11C 16/24; G11C 16/30

(57) ABSTRACT

An example memory device comprises a memory cell array, a page buffer circuit, and a control logic circuit. The memory cell array comprises a plurality of memory cells each storing a plurality of data. The page buffer circuit comprises a plurality of page buffers connected to each memory cell through bit lines, and each page buffer comprises a first node that senses data stored in the memory cell and a second node connected to the first node through a transistor. The control logic circuit controls first and second sensing operations of the page buffer circuit by providing page buffer control signals to the page buffer circuit. Each page buffer stores sensing information of the first sensing operation in the first node and the second node, and performs a charge sharing operation between the first node and the second node according to the sensing information during the second sensing operation.

### CROSS-REFERENCE TO RELATED APPLICATION

This application claims priority under 35 U.S.C. § 119 to Korean Patent Application No. 10-2024-0109970 filed on Aug. 16, 2024, in the Korean Intellectual Property Office, the disclosures of which are incorporated by reference herein in their entirety.

### BACKGROUND

Semiconductor memories may be classified as a volatile memory or a non-volatile memory, for example. Typically, the volatile memories (e.g., a dynamic random access memory (DRAM) or a static random access memory (SRAM)) may exhibit faster read and/or write speeds when compared to the non-volatile memory. However, data stored in the volatile memory may disappear when a power applied to the volatile memory is turned off. In contrast, the non-volatile memory may retain the data even when the power is turned off.

A representative example of the non-volatile memory may be a flash memory. The flash memory may store multi-bit data of two or more bits in one memory cell. The flash memory may have at least one erase state and a plurality of program (e.g., writing) states depending on threshold voltage distributions.

Recently, there is increasing demand for low-power flash memory. In order to implement low-power flash memory, the operating voltage of the flash memory must be lowered. The lowering of the operating voltage of the flash memory naturally requires a lowering of the operating voltage of the page buffer. However, in the circuit structure of a general page buffer, the minimum voltage of the sensing node is related to the level of the bit line, not the operating voltage. Therefore, the bit line voltage does not decrease as much as the operating voltage unless the cell current flowing through the bit line is reduced.

As a result, as the operating voltage of the page buffer decreases, the voltage range formed at the sensing node also decreases relatively. In addition, as the area of the page buffer decreases, the variation of the trip voltage also increases. As a result, it becomes difficult to correctly determine whether the memory cell is on-cell/off-cell at a low operating voltage. In other words, when the operating voltage of the page buffer decreases, it is difficult to secure both the on-cell margin and the off-cell margin.

### SUMMARY

The present disclosure relates to a memory device and a sensing method thereof that increase the sensing margin by performing a charge sharing operation between the SO node and the SOC node of the page buffer.

In general, according to some aspects, a memory device comprises a memory cell array configured to have a plurality of memory cells connected to a word line, each memory cell storing a plurality of data; a page buffer circuit configured to have a plurality of page buffers connected to each memory cell through bit lines, each page buffer having a first node for sensing data stored in the memory cell and a second node connected to the first node through a transistor; and a control logic configured to control first and second sensing operations of the page buffer circuit by providing page buffer control signals to the page buffer circuit. Wherein each page buffer stores sensing information of the first sensing operation in the first node and the second node, and performs a charge sharing operation between the first node and the second node according to the sensing information of the first sensing operation during the second sensing operation, and increases a sensing margin by lowering a voltage level of the first node through the charge sharing operation.

In general, according to some aspects, a memory device comprises a memory cell configured to store a plurality of data; and a page buffer configured to have a first node for sensing data stored in the memory cell, and a second node connected to the first node through a transistor. Wherein the page buffer stores sensing information of a first sensing operation in the first node and the second node, performs a charge sharing operation between the first node and the second node according to the sensing information of the first sensing operation during a second sensing operation, and lowers the voltage level of the first node through the charge sharing operation.

In general, according to some aspects, a sensing method of a memory device which includes a memory cell storing a plurality of data, a page buffer having a first node for sensing data stored in the memory cell and a second node connected to the first node through a transistor, comprises a first sensing operation including a first BL precharge operation for precharging a bit line connected to the memory cell, a first SO precharge operation for precharging the first node, a first SO develop operation for connecting the bit line and the first node, and a first SO sensing operation for sensing the first node; a dump operation for storing a result of the first sensing operation in a sensing latch; and a second sensing operation including a second BL precharge operation for precharging the bit line connected to the memory cell, a second SO precharge operation for precharging the first node, a second SO develop operation for connecting the bit line and the first node, a charge sharing operation for electrically connecting the first node and the second node, and a second SO sensing operation for sensing the first node.

### BRIEF DESCRIPTION OF THE DRAWINGS

The above and other objects and features of the present disclosure will become apparent by describing in detail implementations thereof with reference to the accompanying drawings.

FIG. 1 is a diagram illustrating an example of the reduction in sensing margin of a page buffer due to the lowering of the voltage of a flash memory device.

FIG. 2 is a block diagram illustrating an example of a storage device.

FIG. 3 is a block diagram illustrating an example of the memory device illustrated in FIG. 2.

FIG. 4 is a circuit diagram illustrating an example of a memory block BLK1 of the memory cell array illustrated in FIG. 3.

FIG. 5 is an example circuit diagram illustrating cell strings selected by the first string selection line SSL1 from among the cell strings of the memory block BLK1 illustrated in FIG. 4.

FIG. 6 is a diagram illustrating an example of threshold voltage distributions of memory cells illustrated in FIG. 5.

FIG. 7 is an example circuit diagram illustrating the first page buffer PB1 shown in FIG. 5.

FIG. 8 is a graph illustrating an example of a method of applying selection read voltages to the selection word line shown in FIG. 7.

FIGS. 9 and 10 are example graphs illustrating voltage levels at sensing nodes when the fifth selection read voltage and the first selection read voltage are sequentially applied in the LSB operation.

FIG. 11 is an example timing diagram illustrating the SO node voltage levels of the A to C cell groups during the second sensing operation of FIG. 10.

FIG. 12 is a timing diagram illustrating an example of a sensing operation of the memory device.

FIG. 13 is a circuit diagram illustrating an example of the first page buffer for explaining the first sensing operation shown in FIG. 12

FIGS. 14 and 15 are circuit diagrams illustrating an example of the first page buffer for explaining the dump operation shown in FIG. 12.

FIG. 16 is a timing diagram illustrating an example of a second sensing operation of a memory device.

FIG. 17 and FIG. 18 are example circuit diagrams of the first page buffer for explaining the second SO precharge operation shown in FIG. 16.

FIG. 19 is a diagram illustrating an example of the charge sharing operation of the C cell group shown in FIG. 16.

FIG. 20 is a diagram illustrating an example of a memory device having a multi-stack structure.

FIG. 21 is a block diagram illustrating an example in which a storage device is implemented with a solid state drive (SSD).

### DETAILED DESCRIPTION

Below, example implementations of the present disclosure will be described in detail and clearly to such an extent that an ordinary one in the art easily implements the concepts.

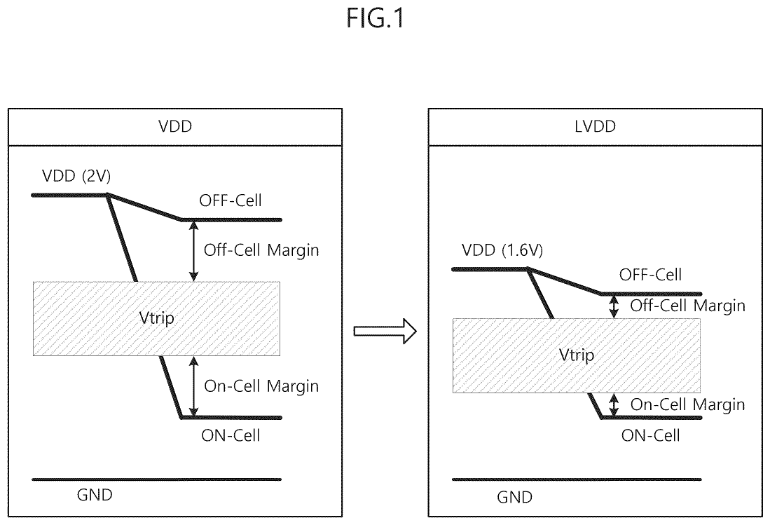

FIG. 1 is a diagram illustrating an example of the reduction in sensing margin of a page buffer due to the lowering of the voltage of a flash memory device. Referring to FIG. 1, as the operating voltage of the page buffer decreases, it becomes difficult to correctly determine whether the sensed memory cell is on-cell or off-cell.

In the case of a page buffer of a general flash memory, the level of a sensing node (hereinafter, SO node) is developed according to the cell current flowing through the bit line. The SO node is directly connected to the sensing latch. Therefore, the trip voltage Vtrip of the page buffer, which distinguishes whether the sensed memory cell is on-cell or off-cell, is the same as the trip voltage of the sensing latch. In addition, since the sensing latch mainly uses a static latch, the trip voltage fluctuation of the sensing latch is also very large.

In order to implement a low-power flash memory, a low voltage of the operating voltage VDD is required. The operating voltage of the page buffer must also be lowered due to the low voltage. At a typical operating voltage (VDD=2V), the on-cell margin and off-cell margin may be sufficiently secured to compensate for the trip voltage fluctuation of the sensing latch. However, it is difficult to secure the off-cell margin in a low operating voltage (e.g., LVDD=1.6V) environment. This is because the minimum voltage of the SO node SO is related to the cell current flowing in the bit line BL.

In other words, the bit line voltage does not decrease as much as the operating voltage decreases without reducing the cell current flowing through the bit line. Therefore, the voltage range formed at the sensing node SO of the page buffer in a low operating voltage (e.g., LVDD=1.6V) environment is greatly reduced. In addition, as the area of the page buffer decreases, the fluctuation of the trip voltage also increases. For this reason, it is difficult to sufficiently secure the on-cell margin or the off-cell margin in a low operating voltage LVDD environment. The present disclosure provides a technology that can sufficiently secure both on-cell margin and off-cell margin in a low operating voltage LVDD environment.

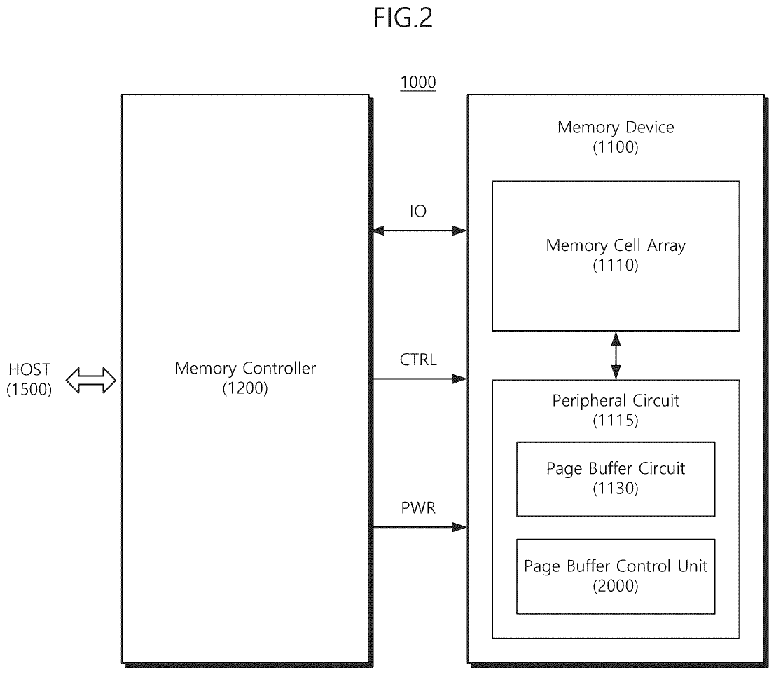

FIG. 2 is a block diagram illustrating an example of a storage device. Referring to FIG. 2, the storage device 1000 may include a memory device 1100 and a memory controller 1200. The storage device 1000 may be a flash storage device based on a flash memory. For example, the storage device 1000 may be implemented as a solid-state drive (SSD), a universal flash storage (UFS), a memory card, or the like.

The storage device 1000 may communicate with the host 1500 through a host interface. The storage device 1000 may receive a write request to store data in the memory device 1100 or a read request to read data stored in the memory device 1100 from the host 1500. The storage device 1000 may receive a logical address for identifying data from the host 1500.

The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure. The memory cell array 1110 may include a plurality of memory cells. Multi-bit data may be stored in each memory cell.

The memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure.

The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200.

The peripheral circuit 1115 may include a page buffer circuit 1130 and a page buffer control unit 2000. The page buffer control unit 2000 may increase the on-cell margin by controlling the sensing operation of the page buffer circuit 1130. The page buffer control unit 2000 may control the first and second sensing operations of the page buffer circuit 1130 by providing page buffer control signals to the page buffer circuit 1130.

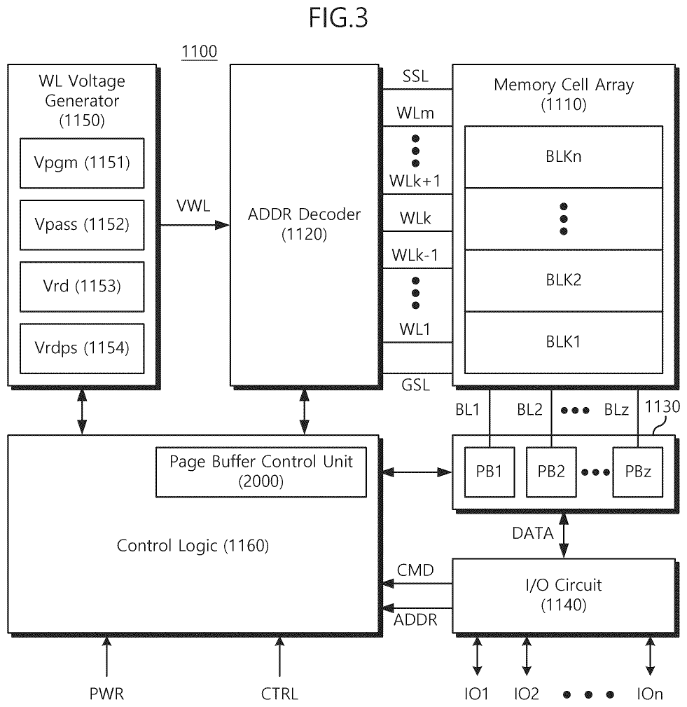

FIG. 3 is a block diagram illustrating an example of the memory device illustrated in FIG. 2. Referring to FIG. 3, the memory device 1100 may include the memory cell array 1110 and the peripheral circuit 1115 (see FIG. 2). The peripheral circuit 1115 may include an address decoder 1120, a page buffer circuit 1130, a data input/output circuit 1140, a word line voltage generator 1150, and a control logic 1160.

The memory cell array 1110 may include a plurality of memory blocks BLK1 to BLKn. Each memory block may include a plurality of pages. Each page may include a plurality of memory cells. Each memory cell may store multi-bit data (e.g., two or more bits). Each memory block may correspond to an erase unit, and each page may correspond to a read unit and/or a write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selection word line sWL and the remaining word lines (WL1 to WLk−1, WLk+1 to WLm) are unselection word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selection word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to IOn. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selection word line sWL or unselection word lines uWL through the address decoder 1120.

The word line voltage generator 1150 may include a program voltage generator 1151 and a pass voltage generator 1152. The program voltage generator 1151 may generate a program voltage Vpgm provided to the selection word line sWL during a program operation. The pass voltage generator 1152 may generate a pass voltage Vpass provided to the selection word line sWL and the unselection word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselection word lines uWL. The read pass voltage Vrdps may be a voltage sufficient to turn on memory cells connected to the unselection word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The control logic 1160 may include a page buffer control unit 2000. The page buffer control unit 2000 may control the first and second sensing operations of the page buffer circuit 1130. The page buffer control unit 2000 may read data stored in a memory cell through the first and second sensing operations. Each page buffer in the page buffer circuit 1130 may store sensing information of the first sensing operation in the first node and the second node, and may perform a charge sharing operation between the first node and the second node according to the sensing information of the first sensing operation during the second sensing operation. The page buffer control unit 2000 may perform the charge sharing operation through page buffer control signals and increase the on-cell margin by lowering the voltage level of the first node of the page buffer.

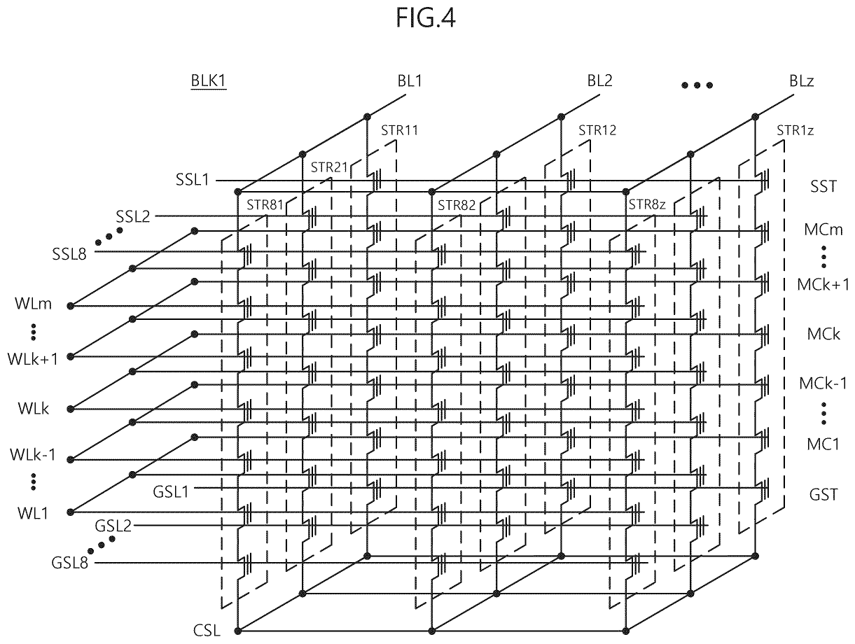

FIG. 4 is a circuit diagram illustrating an example of a memory block BLK1 of the memory cell array illustrated in FIG. 3. Referring to FIG. 4, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLz.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

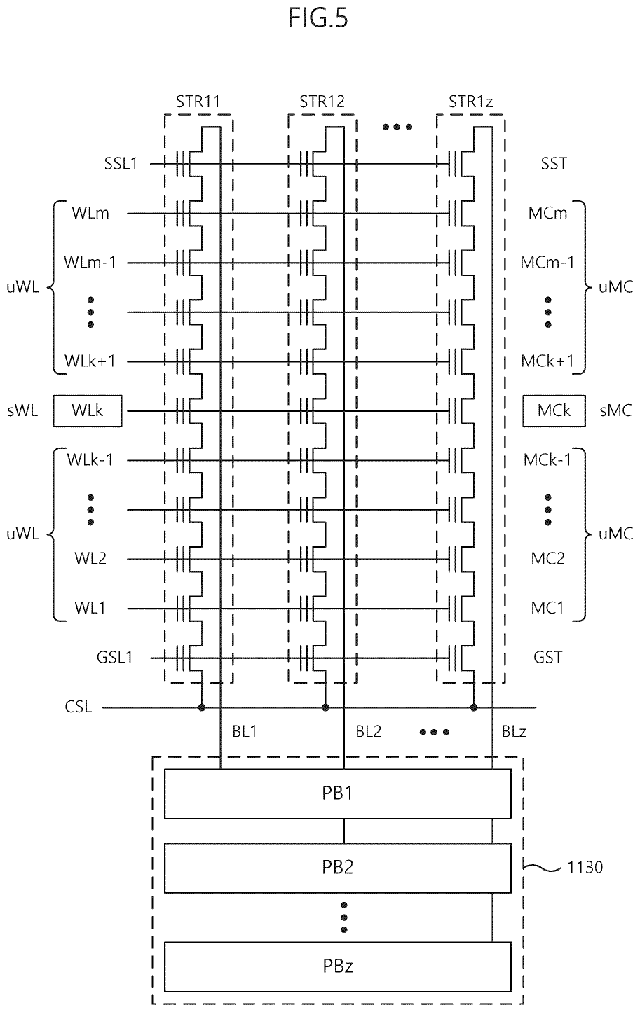

FIG. 5 is an example circuit diagram illustrating cell strings selected by the first string selection line SSL1 from among the cell strings of the memory block BLK1 illustrated in FIG. 4.

The 11th to 1z-th cell strings STR11 to STR1z may be selected by the first string selection line SSL1. The eleventh to 1z-th cell strings STR11 to STR1z may be connected to the first to z-th bit lines BL1 to BLz, respectively. The first to z-th page buffers PB1 to PBz may be connected to the first to z-th bit lines BL1 to BLz, respectively.

The eleventh cell string STR11 may be connected to the first bit line BL1 and the common source line CSL. The eleventh cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The twelfth cell string STR12 may be connected to the second bit line BL2 and the common source line CSL. The 1z cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. The k-th word line WLk may be a selection word line sWL. The (k−1)-th word line WLk−1 and the (k+1)-th word line WLk+1 may be adjacent word lines adjacent to the selection word line. If the k-th word line WLk is the selection word line sWL, the remaining word lines WL1 to WLk−1 and WLk+1 to WLm may be unselection word lines uWL.

The first memory cells MC1 and the m-th memory cells MCm may be edge memory cells. The second memory cells MC2 and the (m−1)-th memory cells MCm−1 may be edge adjacent memory cells. The k-th memory cells MCk may be selection memory cells sMC. The (k−1)-th memory cells MCk−1 and the (k+1)-th memory cells MCk+1 may be memory cells adjacent to the selection memory cells (adjacent MC). If the k-th memory cells MCk are selection memory cells sMC, the remaining memory cells MC1 to MCk−1 and MCk+1 to MCm may be unselection memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selection page, and pages connected to the second to eighth string selection lines SSL2 to SSL8 are unselection pages.

The first word line WL1 is a first edge word line (Edge1 WL), and the second word line WL2 is a first edge adjacent word line (Edge1 adjacent WL). The m-th word line WLm is the second edge word line (Edge2 WL), and the (m−1)-th word line WLm−1 is the second edge adjacent word line (Edge2 adjacent WL). And word lines between the first and second edge adjacent word lines are middle word lines. For example, the k-th word line WLk (k=3 to m−2) between the second word line WL2 and the (m−1)-th word line WLm−1 is a middle word line.

In the read operation, if the second word line WL2 is the selection word line sWL, the remaining word lines may be unselection word lines uWL. The second word line WL2 may be a first edge adjacent word line (Edge1 adjacent WL). The second memory cells MC2 may be selection memory cells sMC. The remaining memory cells may be unselection memory cells uMC.

If the (m−1)-th word line WLm−1 is the selection word line sWL, the remaining word lines may be unselection word lines uWL. The (m−1)-th word line WLm−1 may be a second edge adjacent word line. The (m−1)-th memory cells MCm−1 may be selection memory cells sMC. The remaining memory cells may be unselection memory cells uMC.

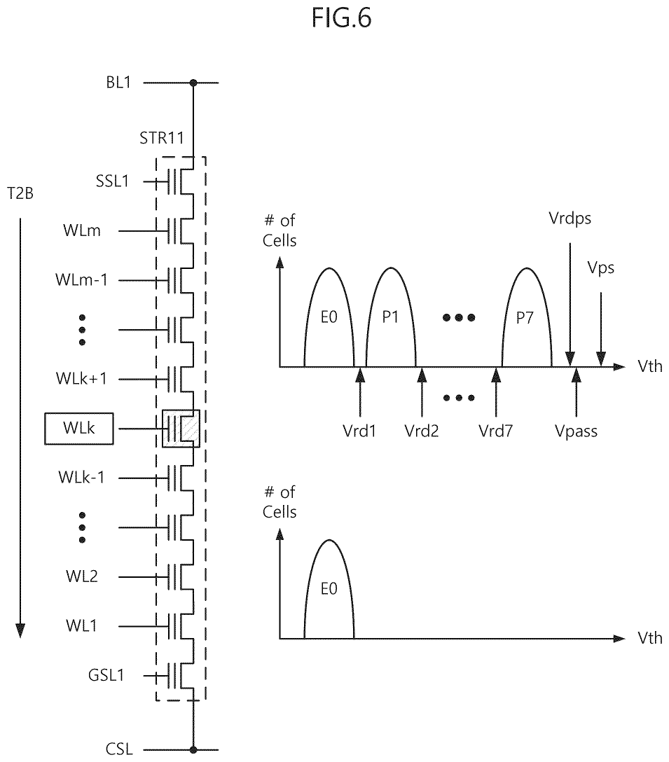

FIG. 6 is a diagram illustrating an example of threshold voltage distributions of memory cells illustrated in FIG. 5. In FIG. 6, an abscissa denotes threshold voltages Vth of memory cells, and an ordinate denotes the number of memory cells (e.g., # of cells). 3-bit data may be stored in one memory cell. A 3-bit memory cell may have one of eight states E0, P1 to P7 according to the threshold voltage distribution. E0 represents an erase state, and P1 to P7 represent program states.

During a read operation, the selection read voltages Vrd1 to Vrd7 may be provided to the selection word line sWL, and the pass voltage Vps and/or the read pass voltage Vrdps may be provided to the unselection word lines uWL. The pass voltage Vps and/or the read pass voltage Vrdps may be a voltage sufficient to turn on the memory cells. For example, the pass voltage Vps may be provided to the adjacent word lines WLk±1, and the read pass voltage Vrdps may be provided to the unselection word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

When the first selection read voltage Vrd1 is applied, the memory cell in the erase state E0 may be an on cell and the memory cell in the first to seventh program states P1 to P7 may be an off cell. When the second selection read voltage Vrd2 is applied, the memory cell in the erase state E0 and the first program state P1 may an on cell, and the memory cell in the second to seventh program states P2 to P7 may an off cell. In this way, when the seventh selection read voltage Vrd7 is applied, the memory cell in the erase state E0 and the first to sixth program states P1 to P6 may be an on cell and the memory cell in the seventh program state P7 may be an off cell.

During a read operation, the k-th word line WLk may be selected. A power supply voltage may be applied to the string selection line SSL1 and the ground selection line GSL1, and the string select transistor SST and the ground select transistor GST may be turned on. Also, the selection read voltage Vrd may be provided to the selection word line sWL, and the read pass voltage Vrdps and/or the pass voltage Vps may be provided to the unselection word lines uWL.

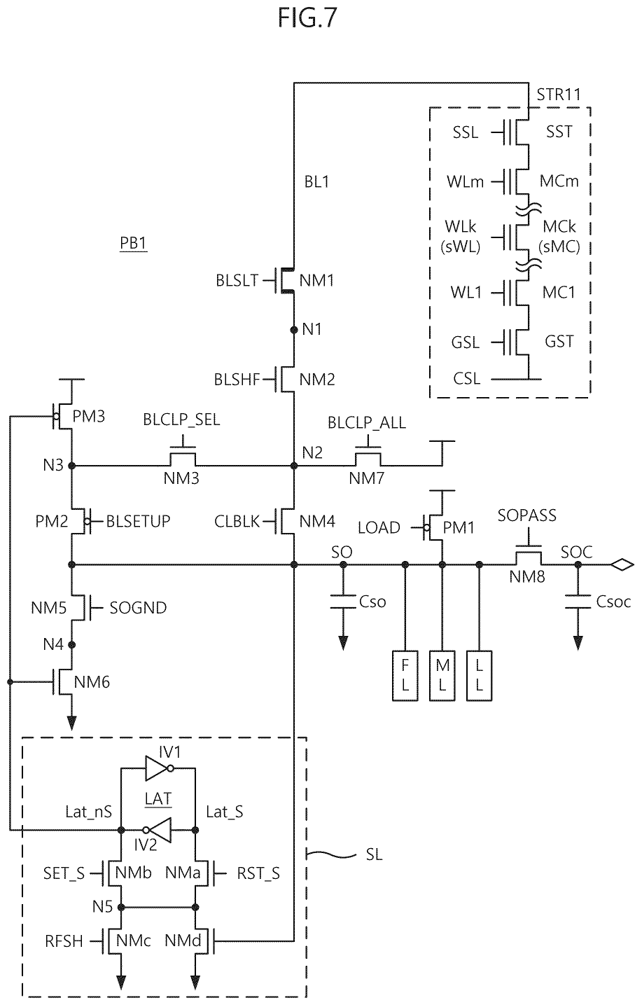

FIG. 7 is an example circuit diagram illustrating the first page buffer PB1 shown in FIG. 5. Referring to FIG. 7, the first page buffer PB1 may be connected to the first bit line BL1. A cell string may be connected to the first bit line BL1.

The cell string may include a string select transistor SST, a plurality of memory cells MC1 to MCm, and a ground select transistor GST. The cell string may be connected between the first bit line BL1 and the common source line CSL. The cell string may include a string selection transistor SST selected by a string selection line SSL, first to m-th memory cells MC1 to MCm connected to the first to m-th word lines WL1 to WLm, and a ground selection transistor GST selected by the ground selection line GSL. The k-th memory cell MCk may be a selection memory cell, and the k-th word line WLk may be a selection word line.

The first page buffer (PB1) may be connected to the cell string through the first bit line BL1. A first NMOS transistor NM1 may be included between the first bit line BL1 and the first node N1. The first NMOS transistor NM1 may be a bit line select transistor driven by the bit line select signal BLSLT. The bit line select transistor may be implemented as a high voltage transistor. The bit line select transistor may be disposed in the high voltage region.

A second NMOS transistor NM2 may be included between the first node N1 and the second node N2. The second NMOS transistor NM2 may be a bit line shut-off transistor driven by the bit line shut-off signal BLSHF. A third NMOS transistor NM3 may be included between the second node N2 and the third node N3. The third NMOS transistor NM3 may be a bit line clamping transistor driven by the bit line clamping control signal BLCLAMP. A fourth NMOS transistor NM4 may be included between the second node N2 and the sensing node SO. The fourth NMOS transistor NM4 may be a bit line connection transistor driven by the bit line connection control signal CLBLK.

A first PMOS transistor PM1 may be included between the sensing node SO and the power terminal. The first PMOS transistor PM1 may be a precharge load transistor driven by the load signal LOAD. A second PMOS transistor PM2 may be included between the sensing node SO and the third node NM3. The second PMOS transistor PM2 may be a bit line setup transistor driven by the bit line setup signal BLSETUP. A third PMOS transistor PM3 may be included between the third node NM3 and the power terminal. The third PMOS transistor PM3 may be a precharge transistor driven by the inverted latch node Lat_nS.

A fifth NMOS transistor NM5 may be included between the SO node and the fourth node N4. The fifth NMOS transistor NM5 may be a sensing node ground transistor driven by the SOGND signal. A sixth NMOS transistor NM6 may be included between the fourth node N4 and the ground terminal. The sixth NMOS transistor NM6 may be a discharge transistor driven by the Lat_nS node.

A seventh NMOS transistor NM7 may be included between the second node N2 and the power terminal. The seventh NMOS transistor NM7 may be a bit line clamp transistor driven by a BLCLP_ALL signal. The bit line clamp transistor may be used to precharge the bit line during a read operation.

An eighth NMOS transistor NM8 may be included between the SO node and the SOC node. The eighth NMOS transistor NM8 may be a sensing node pass transistor driven by a SOPASS signal. The SO node may have Cso capacitance, and the SOC node may have Csoc capacitance.

A sensing latch SL, a force latch FL, a most significant bit latch ML, and a least significant bit latch LL may be connected to the sensing node SO. The sensing latch SL may store data stored in the selection memory cell sMC or a sensing result of the threshold voltage of the selection memory cell sMC during a read or program verify operation. Also, the sensing latch SL may be used to apply a program bit line voltage or a program inhibit voltage to the first bit line BL1 during a program operation. The force latch FL may be used to improve threshold voltage distribution during a program operation. The most significant bit latch ML and the least significant bit latch LL may be utilized to store data inputted from the outside during a program operation.

The sensing latch SL may include a latch LAT connected between the latch node Lat_S and the inverted latch node Lat_nS. The latch LAT may include first and second inverters INV1 and INV2. An input terminal of the first inverter INV1 and an output terminal of the second inverter INV2 may be connected to the inverted latch node Lat_nS. An output terminal of the first inverter INV1 and an input terminal of the second inverter INV2 may be connected to the latch node Lat_S.

The inverted latch node Lat_nS may be connected to the gate terminal of the third PMOS transistor PM3. When the inverted latch node Lat_nS is at a low level, the third PMOS transistor PM3 may be turned on, and the third node N3 may become a power supply voltage level. When the inverted latch node Lat_nS is at a high level, the power terminal and the third node N3 may be cut off.

A a-th NMOS transistor NMa may be included between the latch node Lat_S and the fifth node N5. The a-th NMOS transistor NMa may be used to reset the latch node Lat_S in response to the latch reset signal RST_S. The latch reset signal RST_S may be provided from the control logic 1160. A b-th NMOS transistor NMb may be included between the inverted latch node Lat_nS and the fifth node N5. The b-th NMOS transistor NMb may be used to set the latch node Lat_S in response to the latch set signal SET_S. The latch set signal SET_S may be provided from the control logic 1160.

A c-th NMOS transistor NMc may be included between the fifth node N5 and the ground terminal. The c-th NMOS transistor NMc may adjust the voltage level of the fifth node N5 in response to the refresh signal RFSH. The refresh signal RFSH may be provided from the control logic 1160. A d-th NMOS transistor NMd may be included between the fifth node N5 and the ground terminal. The d-th NMOS transistor NMd may adjust the voltage level of the fifth node N5 in response to the voltage level of the sensing node SO.

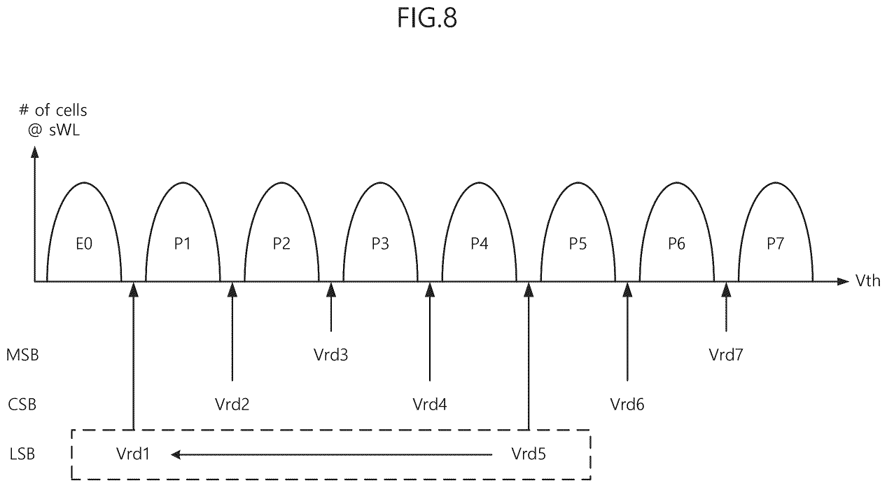

FIG. 8 is a graph illustrating an example of a method of applying selection read voltages to the selection word line shown in FIG. 7. In FIG. 8, an abscissa denotes a threshold voltage Vth of a memory cell, and an ordinate denotes the number of a selection memory cell (e.g., # of cells@sWL) connected to a selection word line sWL.

When 3-bit data is stored in one memory cell, data stored in the memory cell may be read through the LSB operation, the CSB operation, and the MSB operation. The selection read voltage may be applied from the first selection read voltage Vrd1 of the lowest voltage level to the seventh selection read voltage Vrd7 of the highest voltage level.

The order in which the selection read voltages Vrd1 to Vrd7 are applied to the selection word line sWL may be determined in various ways. For example, the first and fifth selection read voltages Vrd1 and Vrd5 may be applied in the LSB operation, then the second, fourth and sixth selection read voltages Vrd2, Vrd4, and Vrd6 may be applied in the CSB operation, and finally the third and seventh selection read voltages Vrd3 and Vrd7 may be applied in the MSB operation.

In addition, the order in which the selection read voltages are applied within each operation may also be determined in various ways. For example, in the LSB operation, the fifth selection read voltage Vrd5 may be applied, and then the first selection read voltage Vrd1 may be applied. Conversely, in the LSB operation, the first selection read voltage Vrd1 may be applied, and then the fifth selection read voltage Vrd5 may be applied.

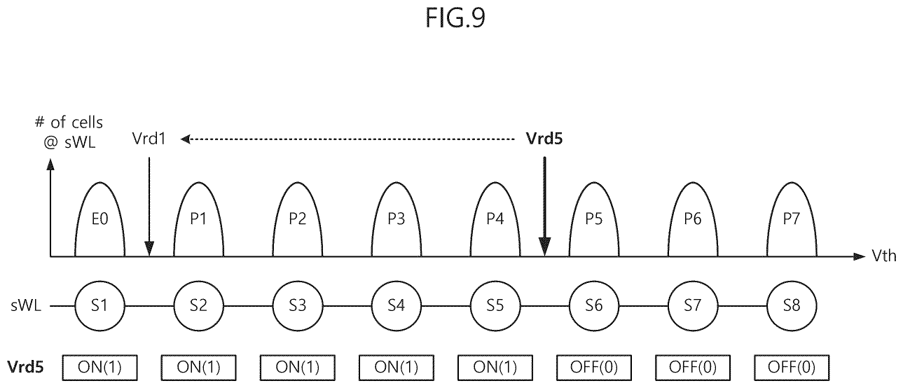

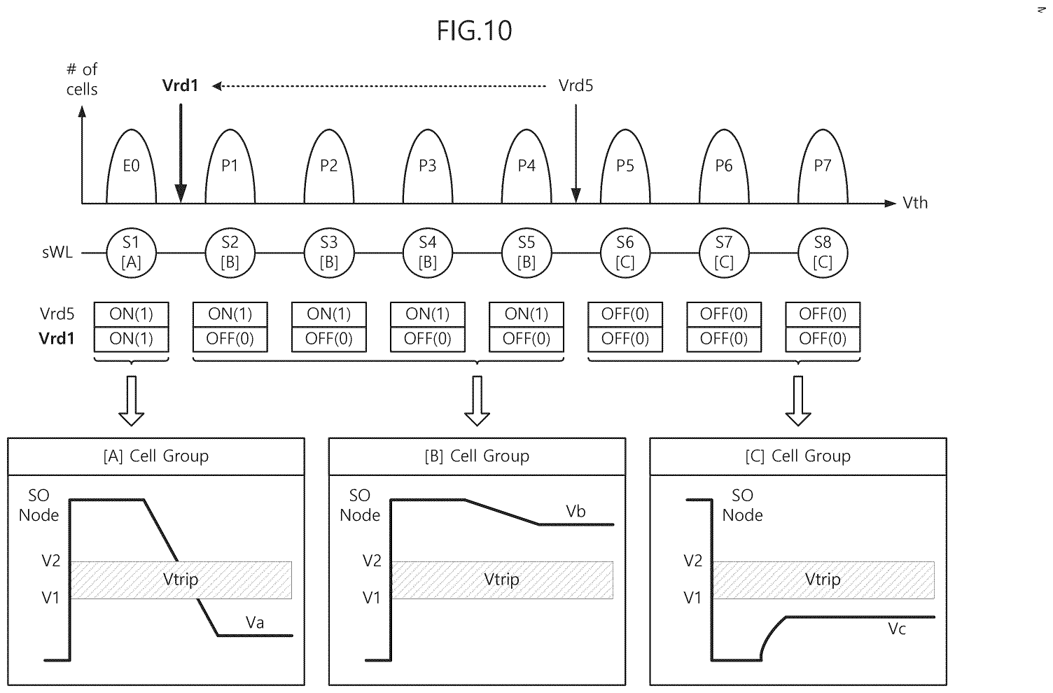

FIGS. 9 and 10 are example graphs illustrating voltage levels at sensing nodes when the fifth selection read voltage and the first selection read voltage are sequentially applied in the LSB operation. In FIG. 9, the fifth selection read voltage Vrd5 is applied to the selection word line sWL, and then in FIG. 10, the first selection read voltage Vrd1 is applied.

The first to eighth memory cells S1 to S8 may be connected to the selection word line sWL. The first memory cell S1 may be in the erase state E0, and the second to eighth memory cells S2 to S8 are in the first to seventh program states P1 to P7, respectively.

Referring to FIG. 9, a first sensing operation may be performed in which a fifth selection read voltage Vrd5 is applied to a selection word line sWL. When the first sensing operation is performed, the first to fifth memory cells S1 to S5 may be on cells, and the sixth to eighth memory cells S6 to S8 may be off cells. The on cells may store data 1, and the off cells may store data 0.

Referring to FIG. 10, a second sensing operation may be performed in which a first selection read voltage Vrd1 is applied to a selection word line sWL. When the second sensing operation is performed, the first memory cell S1 may be on cells, and the second to eighth memory cells S2 to S8 may be off cells. The on cells may store data 1, and the off cells may store data 0.

The first memory cell S1 may be an on-cell when the first and fifth selection read voltages Vrd1 and Vrd5 are applied to the selection word line sWL. A group of memory cells that are all on-cells when the first and fifth selection read voltages Vrd1 and Vrd5 are applied may be called an A-cell group. When the first and second sensing operations are performed, the SO node of the A-cell group may have a Va level. Assuming that the range of the trip voltage (Vtrip) is from V1 to V2, the on-cell margin of the A-cell group may be V1-Va.

The second to fifth memory cells S2 to S5 may be on-cells when the fifth selection read voltage Vrd5 is applied and off-cells when the first selection read voltage Vrd1 is applied. A group of memory cells that are on-cells when the fifth selection read voltage Vrd5 is applied and are off-cells when the first selection read voltage Vrd1 is applied may be called a B-cell group. When the first and second sensing operations are performed, the SO node of the B-cell group may have a Vb level. The off-cell margin of the B-cell group may be Vb-V2.

The sixth to eighth memory cells S6-S8 may all be off-cells when the first and fifth selection read voltages Vrd1 and Vrd5 are applied. A group of memory cells that are all off-cells when the first and fifth selection read voltages Vrd1 and Vrd5 are applied is called a C-cell group. When the first and second sensing operations are performed, the SO node of the C-cell group may have a Vc level. The Vc level may be higher than the Va level. The cell margin of the C-cell group may be V1-Vc.

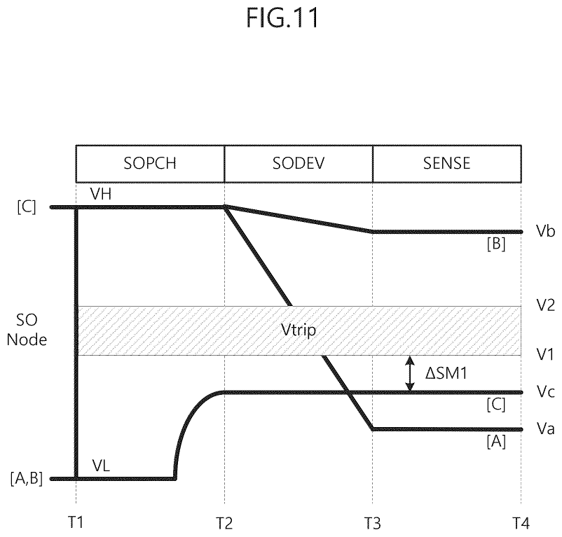

FIG. 11 is an example timing diagram illustrating the SO node voltage levels of the A to C cell groups during the second sensing operation of FIG. 10. The second sensing operation of the memory device 1100 may include an SO precharge operation SOPCH, an SO develop operation SODEV, and an SO sensing operation SENSE.

The SO precharge operation SOPCH may be performed in a time period of T1 to T2. During the SO precharge operation, the SO nodes of the A cell group and the B cell group may have a low level VL, and the SO node of the C cell group may have a high level VH.

The SO develop operation SODEV may be performed in a time period of T2 to T3. During the SO develop operation, the SO node of the A cell group may be lowered to Va, the SO node of the B cell group may have Vb, and the SO node of the C cell group may have Vc.

The SO sensing operation SENSE may be performed in the time period T3 to T4. During the SO sensing operation, the sensing margin of the A cell group may be V1-Va. The sensing margin of the A cell group may be the on-cell margin. The sensing margin of the B cell group may be Vb-V2. The sensing margin of the B cell group may be the off-cell margin. The sensing margin of the C cell group may be V1-Vc.

The on-cell margin of the memory device 1100 may be determined by the C cell group. Since the on-cell margin of the C cell group is V1-Vc, the on-cell margin of the memory device 1100 may be ΔSM1. When the memory device 1100 is reduced in power, not only the off-cell margin but also the on-cell margin is reduced, and an off-cell sensing fail or an on-cell sensing fail problem may occur. The memory device 1100 may solve the on-cell sensing fail problem caused by the C-cell group through charge sharing. According to the present disclosure, the on-cell margin of the memory device 1100 may be increased.

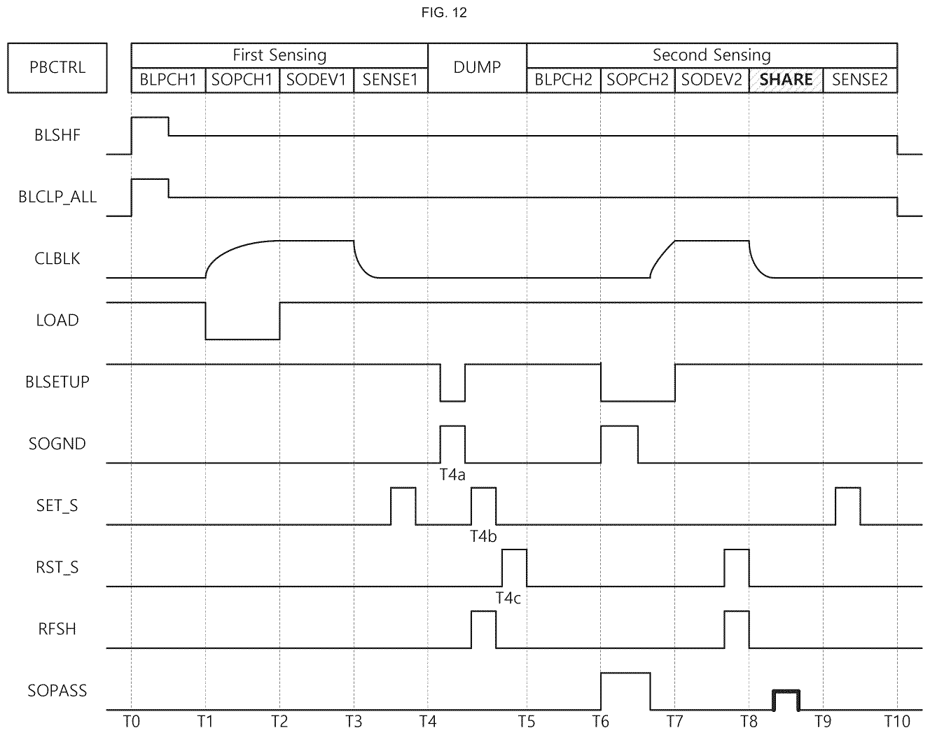

FIG. 12 is a timing diagram illustrating an example of a sensing operation of the memory device. Referring to FIG. 12, the memory device 1100 may perform a first sensing operation, a dump operation, and a second sensing operation. The sensing operation of the memory device 1100 may be an LSB operation. During the first sensing operation, a fifth selection read voltage Vrd5 may be provided to the selection word line sWL, and during the second sensing operation, a first selection read voltage Vrd1 may be provided to the selection word line sWL.

The first sensing operation may include a first BL precharge operation BLPCH1, a first SO precharge operation SOPCH1, a first SO develop operation SODEV1, and a first SO sensing operation SENSE1. The second sensing operation may include a second BL precharge operation BLPCH2, a second SO precharge operation SOPCH2, a second SO develop operation SODEV2, a charge sharing operation SHARE, and a second SO sensing operation SENSE2. During the first sensing operation, the dump operation, and the second sensing operation, page buffer control signals PBCTRL may be provided from the page buffer control unit (see FIGS. 3, 2000).

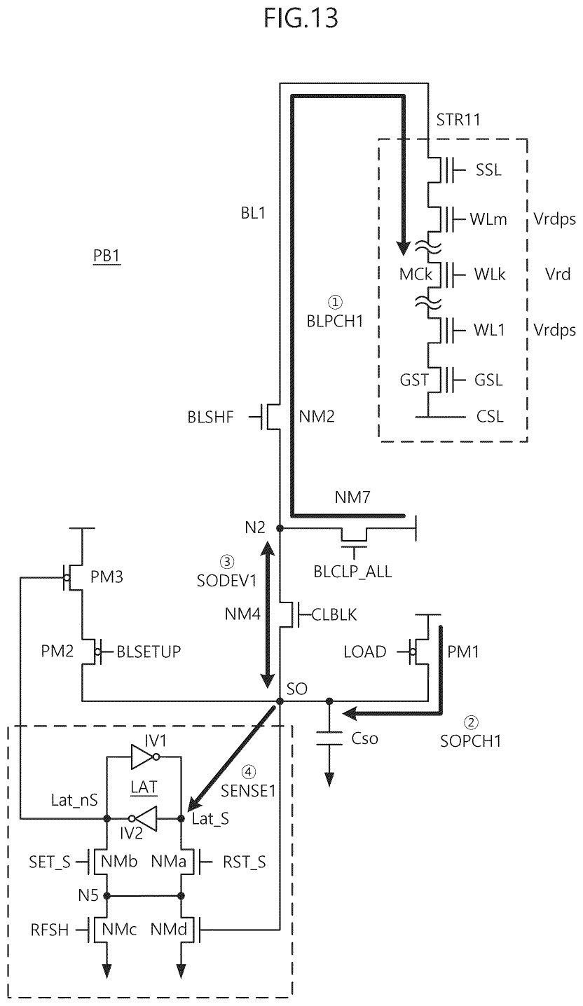

FIG. 13 is a circuit diagram illustrating an example of the first page buffer for explaining the first sensing operation shown in FIG. 12. Referring to FIGS. 12 and 13, the first page buffer PB1 may perform a first BL precharge operation BLPCH1. In the first BL precharge time period T0 to T1, a BLSHF signal and a BLCLP_ALL signal may be provided from the page buffer control unit 2000. When the BLSHF signal and the BLCLP_ALL signal are provided, the second NMOS transistor NM2 and the seventh NMOS transistor NM7 may be turned on. At this time, the fourth NMOS transistor NM4 may be turned off.

During the first BL precharge operation, the page buffer internal voltage may be provided to the first bit line BL1 through the seventh NMOS transistor NM7. A voltage level of the second node N2 may rise to the page buffer internal voltage.

The first page buffer PB1 may perform a first SO precharge operation SOPCH1 in the first SO precharge time period T1 to T2. During the first SO precharge operation, a LOAD signal may be provided from the page buffer control unit 2000. When the LOAD signal is provided, the first PMOS transistor PM1 may be turned on. During the first SO precharge operation, a page buffer internal voltage may be provided to the SO node through the first PMOS transistor PM1. A voltage level of the SO node may rise to the page buffer internal voltage.

The first page buffer PB1 may perform a first SO develop operation SODEV1 in the first SO develop time period T2 to T3. During the first SO develop operation, a CLBLK signal may be provided from the page buffer control unit 2000. When the CLBLK signal is provided, the fourth NMOS transistor NM4 may be turned on. When the fourth NMOS transistor NM4 is turned on, charge sharing may be performed between the first bit line BL1 and the SO node.

The voltage level of the SO node may vary depending on whether the k-th memory cell MCk is an on cell or an off cell. If the k-th memory cell MCk is an on cell, the charge precharged in the bit line may be discharged through the common source line CSL. The voltage level of the SO node may be lowered below the trip voltage level. If the k-th memory cell MCk is an off cell, the charge precharged in the bit line may not be discharged, so the voltage level of the SO node may be maintained above the trip voltage level.

The first page buffer PB1 may perform the first SO sensing operation SENSE1 in the first SO sensing time period T3 to T4. During the first SO sensing operation, if the k-th memory cell MCk is an off cell, the SO node may maintain the precharge voltage level, and the d-th NMOS transistor NMd may be turned on. When the SET_S signal is provided, the b-th NMOS transistor NMb may be turned on, the Lat_nS node may be at a low level VL, and the Lat_S node may be at a high level VH.

If the k-th memory cell MCk is an on cell, the SO node may be a ground level, and the d-th NMOS transistor NMd may be turned off. The latch LAT may maintain its initial state. That is, the Lat_S node may maintain a low level VL, and the Lat_nS node may maintain a high level VH. As a result of the SO sensing operation, the level of the SO node may be reflected in the Lat_S node.

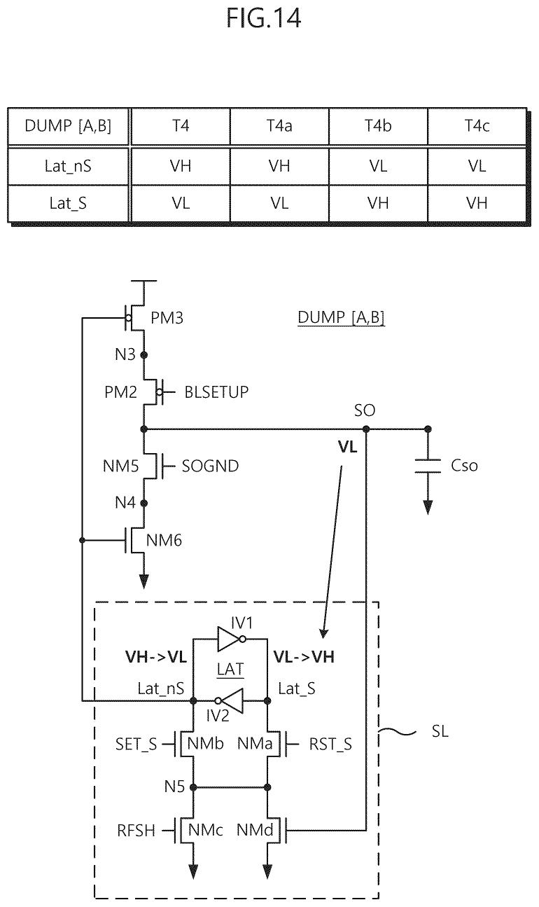

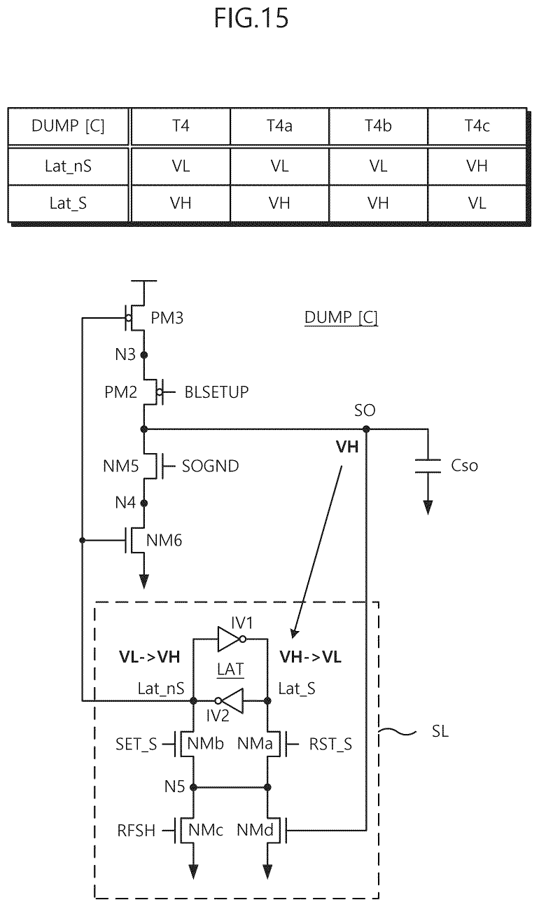

FIGS. 14 and 15 are circuit diagrams illustrating an example of the first page buffer for explaining the dump operation shown in FIG. 12. FIG. 14 shows the dump operation(DUMP[A, B] of the A cell group and the B cell group, and FIG. 15 shows the dump operation DUMP[C] of the C cell group.

Referring to FIG. 12 and FIG. 14, at time T4, the SO node of the A cell group and the B cell group may have a low level VL, the Lat_nS node may have a high level VH, and the Lat_S node may have a low level VL.

At time T4a, when the BLSETUP signal and the SOGND signal are provided from the page buffer control unit 2000, the second PMOS transistor PM2 and the fifth NMOS transistor NM5 may be turned on. Since the Lat_nS node is at a high level VH, the third PMOS transistor PM3 may be turned off and the sixth NMOS transistor NM6 may be turned on. Since the fifth NMOS transistor NM5 and the sixth NMOS transistor NM6 are turned on, the SO node may be maintained at a low level VL.

At time T4b, when the SET_S signal and the RFSH signal are provided from the page buffer control unit 2000, the b-th NMOS transistor NMb and the c-th NMOS transistor NMc may be turned on. When the b-th NMOS transistor NMb and the c-th NMOS transistor NMc are turned on, the Lat_nS node may be at a low level VL and the Lat_S node may be at a high level VH. Since the Lat_nS node is at a low level VL, the third PMOS transistor PM3 may be turned on and the sixth NMOS transistor NM6 may be turned off. Since the second PMOS transistor PM2 and the fifth NMOS transistor NM5 are turned off, the SO node may maintain a low level VL.

At time T4c, when the RST_S signal is provided from the page buffer control unit 2000, the a-th NMOS transistor NMa may be turned on. Since the c-th NMOS transistor NMc and the d-th NMOS transistor NMd are turned off, the SO node may maintain a low level VL, and the Lat_S node may maintain a high level VH. The SO nodes of the A cell group and the B cell group may maintain the low level VL during the dump operation, while the Lat_S node may change to the high level VH.

Referring to FIG. 12 and FIG. 15, at time T4, the SO node of the C cell group may have a high level VH, the Lat_nS node may have a low level VL, and the Lat_S node may have a high level VH.

At time T4a, when the BLSETUP signal and the SOGND signal are provided from the page buffer control unit 2000, the second PMOS transistor PM2 and the fifth NMOS transistor NM5 may be turned on. Since the Lat_nS node is at a low level VL, the third PMOS transistor PM3 may be turned on and the sixth NMOS transistor NM6 may be turned off. Since the second PMOS transistor PM2 and the third PMOS transistor PM3 are turned on, the SO node may maintain a high level VH.

At time T4b, when the SET_S signal and the RFSH signal are provided from the page buffer control unit 2000, the b-th NMOS transistor NMb and the c-th NMOS transistor NMc may be turned on. When the b-th NMOS transistor NMb and the c-th NMOS transistor NMc are turned on, the Lat_nS node may maintain a low level VL and the Lat_S node may maintain a high level VH. Since the Lat_nS node is at a low level VL, the third PMOS transistor PM3 may be turned on and the sixth NMOS transistor NM6 may be turned off. Since the second PMOS transistor PM2 and the fifth NMOS transistor NM5 are turned off, the SO node may maintain a high level VH.

At time T4c, when the RST_S signal is provided from the page buffer control unit 2000, the a-th NMOS transistor NMa may be turned on. Since the SO node is at a high level VH, the d-th NMOS transistor NMd may be turned on. When the a-th NMOS transistor NMa and the d-th NMOS transistor NMd are turned on, the Lat_S node may be changed to a low level VL and the Lat_nS node may be changed to a high level VH. While the SO node of the C cell group maintains the high level VH during the dump operation, the Lat_S node may change from the high level VH to the low level VL.

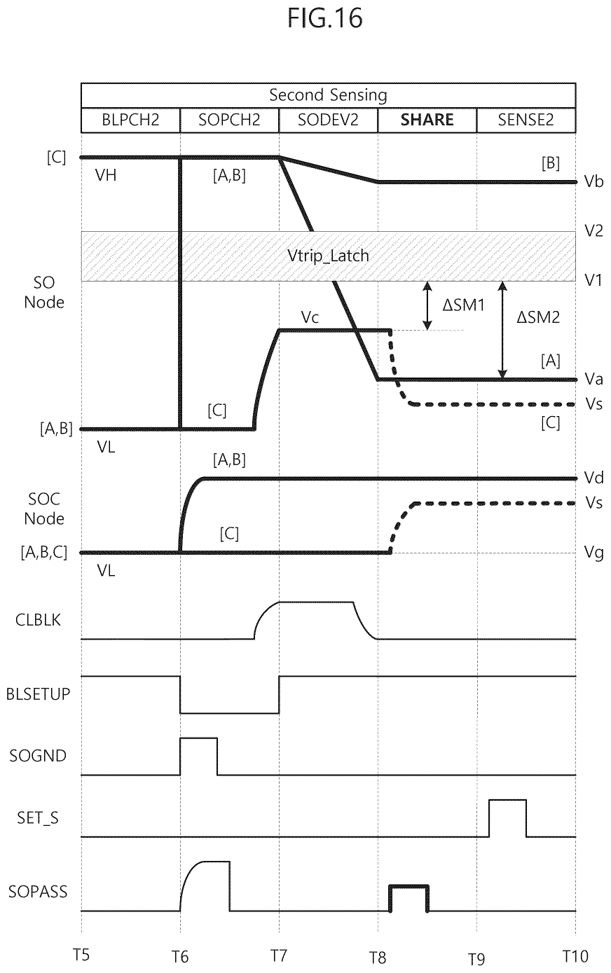

FIG. 16 is a timing diagram illustrating an example of a second sensing operation of a memory device. During the first sensing operation, a fifth selection read voltage Vrd5 may be provided to the selection word line sWL. And during the second sensing operation, a first selection read voltage Vrd1 may be provided to the selection word line sWL.

The second sensing operation may include a second BL precharge operation BLPCH2, a second SO precharge operation SOPCH2, a second SO develop operation SODEV2, a charge sharing operation SHARE, and a second SO sensing operation SENSE2.

The first page buffer PB1 may perform the second BL precharge operation BLPCH2 after the dump operation. In the second bit line precharge time period T5 to T6, the page buffer internal voltage may be provided to the first bit line BL1 through the seventh NMOS transistor (see FIG. 13, NM7). In the second bit line precharge time period T5 to T6, the SO nodes of the A cell group and the B cell group may maintain a low level VL, and the C cell group may maintain a high level VH.

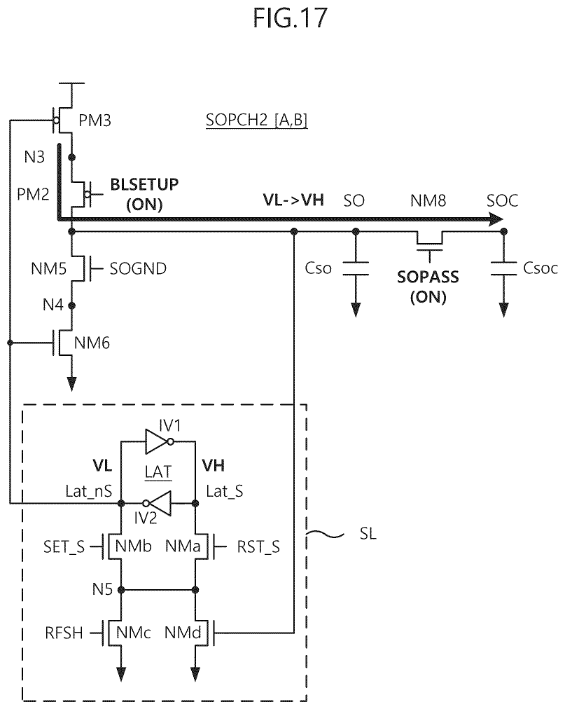

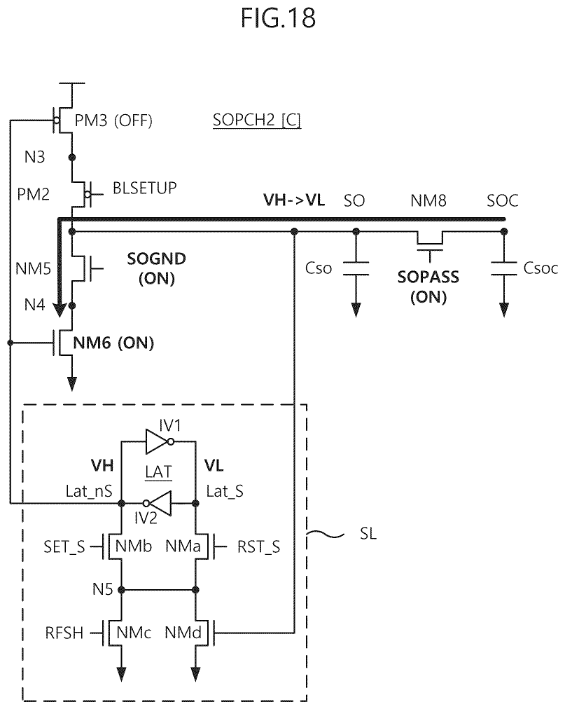

FIG. 17 and FIG. 18 are example circuit diagrams of the first page buffer for explaining the second SO precharge operation shown in FIG. 16. The first page buffer PB1 may perform the second SO precharge operation SOPCH2 in the second SO precharge time period T6 to T7. FIG. 17 shows the second SO precharge operation SOPCH2[A, B] of the A cell group and the B cell group, and FIG. 18 shows the second SO precharge operation SOPCH2[C] of the C cell group.

Referring to FIGS. 16 and 17, during the second SO precharge time period T6 to T7, the voltage levels of the SO nodes of the A cell group and the B cell group may rise from a low level VL to a high level VH. The Lat_nS node may have a low level VL, and the Lat_S node may have a high level VH.

During the second SO precharge operation, a BLSETUP signal and a SOGND signal may be provided from the page buffer control unit 2000. When the BLSETUP signal is provided, the second PMOS transistor PM2 may be turned on. Since the Lat_nS node is at a low level VL, the third PMOS transistor PM3 may be turned on, and the sixth NMOS transistor NM6 may be turned off. The page buffer internal voltage may be provided to the SO node through the third PMOS transistor PM3. The voltage level of the SO node may rise from a low level VL to a high level VH.

During the second SO precharge operation, a SOPASS signal may be provided from the page buffer control unit 2000. When the SOPASS signal is provided, the eighth NMOS transistor NM8 may be turned on. When the eighth NMOS transistor NM8 is turned on, the voltage level of the SOC node may rise to the Vd level.

During the second SO precharge operation, the voltage levels of the SO nodes of the A cell group and the B cell group may rise from a low level VL to a high level VH. The voltage levels of the SOC nodes of the A cell group and the B cell group may rise from the Vg level to the Vd level. Here, the Vd level may be a difference between the gate voltage and the threshold voltage of the eighth NMOS transistor NM8. The Vg level may be a ground voltage level.

Referring to FIG. 16 and FIG. 18, during the second SO precharge time period T6 to T7, the SO node voltage level of the C cell group may drop from a high level VH to a low level VL. The Lat_nS node may have a high level VH, and the Lat_S node may have a low level VL.

During the second SO precharge operation, the BLSETUP signal and the SOGND signal may be provided from the page buffer control unit 2000. When the SOGND signal is provided, the fifth NMOS transistor NM5 may be turned on. Since the Lat_nS node is at a high level VH, the third PMOS transistor PM3 may be turned off and the sixth NMOS transistor NM6 may be turned on.

During the second SO precharge operation, the charge of the SO node may be discharged to the ground terminal through the fifth NMOS transistor NM5 and the sixth NMOS transistor NM6. The voltage level of the SO node may be lowered from the high level VH to the low level VL. Here, the low level VL may be a ground level.

During the second SO precharge operation, the SOPASS signal may be provided from the page buffer control unit 2000. When the SOPASS signal is provided, the eighth NMOS transistor NM8 may be turned on. When the eighth NMOS transistor NM8 is turned on, the voltage level of the SOC node may be a Vg level. Here, the Vg level may be a ground level. During the second SO precharge operation, the SO node voltage level and the SOC node voltage level of the C cell group may be grounded.

Referring again to FIG. 16, the first page buffer PB1 may perform the second SO develop operation SODEV2 in the second SO develop time period T7 to T8. During the second SO develop operation, the CLBLK signal may be provided from the page buffer control unit 2000. When the CLBLK signal is provided, the fourth NMOS transistor NM4 may be turned on. When the fourth NMOS transistor NM4 is turned on, charge sharing may be performed between the first bit line BL1 and the SO node.

When the first selection read voltage Vrd1 is provided to the selection word line sWL, the voltage level of the SO node may vary depending on whether the selection memory cell (e.g., MCk) is an on-cell or an off-cell. The A cell group may be an on cell, and the B cell group and the C cell group may be off cells.

If the k-th memory cell MCk is an A cell group, the voltage level of the SO node may be lowered to Va because the charge precharged to the bit line is discharged through the common source line CSL. If the k-th memory cell MCk is a B cell group, the voltage level of the SO node may have Vb higher than Va because the charge precharged to the bit line is maintained.

If the k-th memory cell MCk is a C cell group, the voltage level of the SO node may rise from a low level VL to Vc because the charge precharged to the bit line is maintained. Here, the Vc level may be determined by the difference between the gate voltage and the threshold voltage of the fourth NMOS transistor NM4.

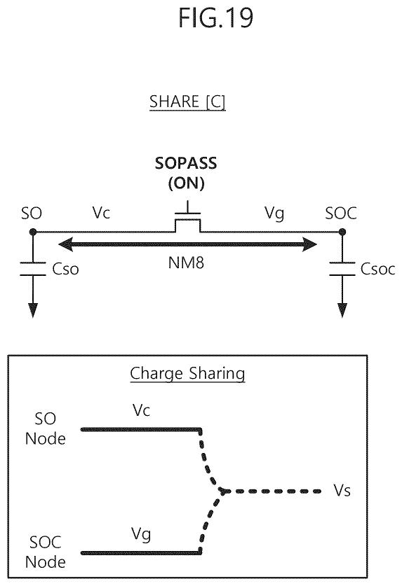

FIG. 19 is a diagram illustrating an example of the charge sharing operation of the C cell group shown in FIG. 16. The first page buffer PB1 may perform a charge sharing operation SHARE between the SO node and the SOC node during the charge sharing time period T8 to T9.

During the charge sharing operation, a SOPASS signal may be provided from the page buffer control unit 2000. When the SOPASS signal is provided, the eighth NMOS transistor NM8 may be turned on. When the eighth NMOS transistor NM8 is turned on, charge sharing may be performed between the SO node and the SOC node.

Referring to FIG. 16 and FIG. 19, the SO node voltage level of the C cell group may be Vc and the SOC node voltage level may be Vg. When the charge sharing operation is performed, the voltage levels of the SO node and the SOC node may have a sharing voltage Vs. During the charge sharing operation SHARE, the SO node voltage level of the C cell group may be lowered from Vc to Vs.

Referring to FIG. 16, the first page buffer PB1 may perform the second SO sensing operation SENSE2 in the second SO sensing time period T9 to T10. During the second SO sensing operation, when the SET_S signal is provided, the b-th NMOS transistor NMb may be turned on. The sensing result of the SO node may be reflected in the Lat_S of the sensing latch SL.

The on-cell margin of the A cell group may be V1-Va. The off-cell margin of the B cell group may be Vb-V2. The on-cell margin of the C cell group may be V1-Vs. If the first page buffer PB1 does not perform the charge sharing operation SHARE, the sensing margin of the C cell group may be V1-Vc. When the first page buffer PB1 performs the charge sharing operation SHARE, the sensing margin of the C cell group may be V1-Vs.

When the memory device 1100 does not perform the charge sharing operation SHARE, the on-cell margin of the C cell group may be ΔSM1. Here, ΔSM1 may be V1-Vc. The on-cell margin of the memory device 1100 may be ΔSM1. The memory device 1100 according to an implementation of the present disclosure may lower the SO node voltage level of the C cell group through the charge sharing operation. According to the present disclosure, the on-cell margin of the memory device 1100 may be ΔSM2. Here, ΔSM2 may be V1-Va.

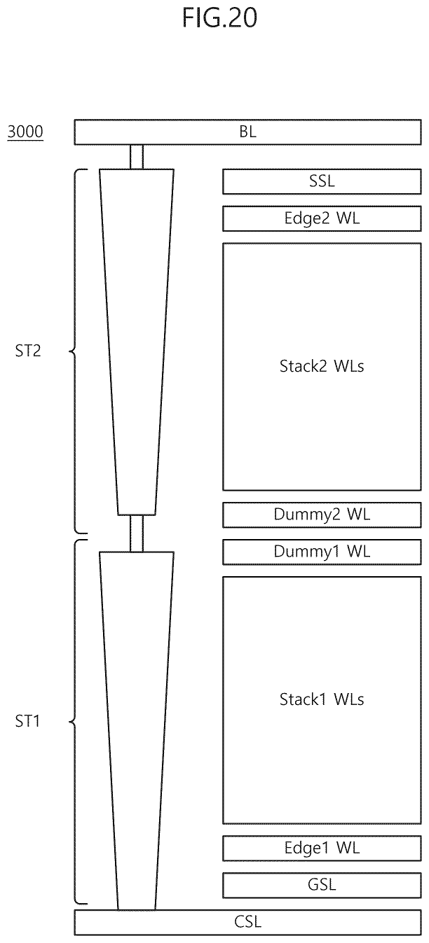

FIG. 20 is a diagram illustrating an example of a memory device having a multi-stack structure. Referring to FIG. 20, the memory device 3000 may have a first stack ST1 and a second stack ST2. The first stack ST1 may be located at the bottom, and the second stack ST2 may be located at the top.

A pillar of the memory device 3000 may be formed by bonding the first and second stacks ST1 and ST2. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

The memory device 3000 may increase the on-cell margin by controlling the sensing operation of the page buffer circuit (see FIGS. 3, 1130). Each page buffer in the memory device 3000 may store the sensing information of the first sensing operation in the SO node and the SOC node, perform a charge sharing operation between the SO node and the SOC node according to the sensing information of the first sensing operation during the second sensing operation, and increase the sensing margin by lowering the voltage level of the SO node through the charge sharing operation.

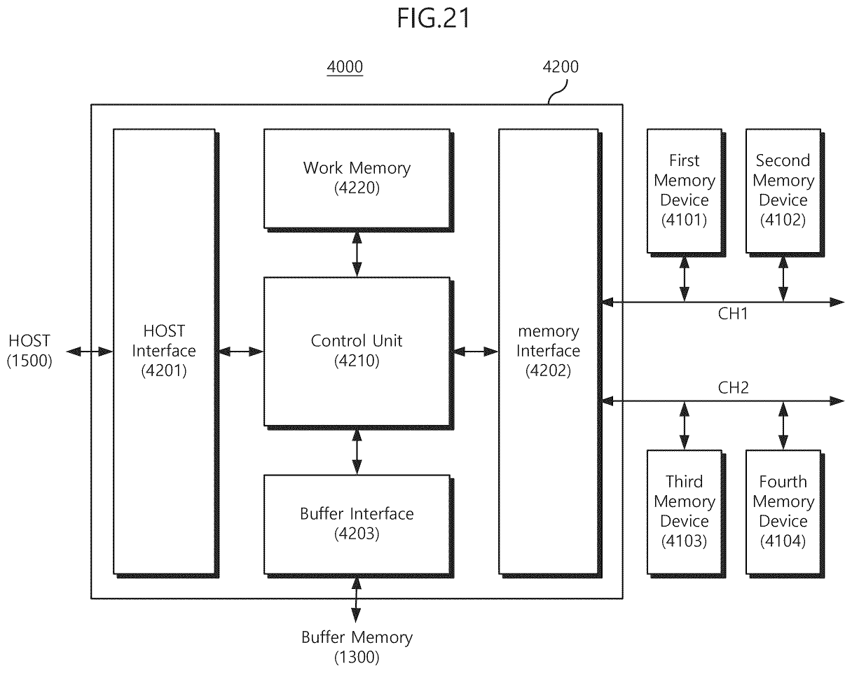

FIG. 21 is a block diagram illustrating an example in which a storage device is implemented with a solid state drive (SSD). Referring to FIG. 21, an SSD 4000 may include a plurality of memory devices 4101 to 4104 and an SSD controller 4200.

The first and second memory devices 4101 and 4102 may be connected with the SSD controller 4200 through a first channel CH1. The third and fourth memory devices 4103 and 4104 may be connected with the SSD controller 4200 through a second channel CH2. The number of channels connected with the SSD controller 4200 may be 2 or more. The number of memory devices connected with one channel may be 2 or more.

The SSD controller 4200 may include a host interface 4201, a memory interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding memory device or may read data from the corresponding memory device.

The SSD controller 4200 may be connected with the plurality of memory devices 4101 to 4104 through the memory interface 4202 and may be connected with a buffer memory 1300 through the buffer interface 4203. The memory interface 4202 may provide data, which are temporarily stored in the buffer memory 1300, to the plurality of memory devices through the channels CH1 and CH2. The memory interface 4202 may transfer the data read from the plurality memory devices 4101 to 4104 to the buffer memory 1300.

The control unit 4210 may analyze and process the signal received from the host 1500. The control unit 4210 may control the host 1500 or the plurality memory devices 4101 to 4104 through the host interface 4201 or the memory interface 4202. The control unit 4210 may control operations of the plurality memory devices 4101 to 4104 by using firmware for driving the SSD 4000.

The SSD controller 4200 may manage data to be stored in the plurality of memory devices 4101 to 4104. In a sudden power-off event, the SSD controller 4200 may back up the data stored in the work memory 4220 or the buffer memory 1300 to the plurality of memory devices 4101 to 4104.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array comprising a plurality of memory cells connected to a word line, each memory cell of the plurality of memory cells being configured to store a plurality of data;
a page buffer circuit comprising a plurality of page buffers, the plurality of page buffers being connected to each memory cell of the plurality of memory cells through a plurality of bit lines, each page buffer of the plurality of page buffers comprising a first node and a second node, the first node being configured to sense data stored in the plurality of memory cells, and the second node being connected to the first node through a transistor; and
a control logic circuit configured to provide a plurality of page buffer control signals to the page buffer circuit, wherein the plurality of page buffer control signals are configured to control a first sensing operation and a second sensing operation of the page buffer circuit,
wherein each page buffer of the plurality of page buffers is configured to
store sensing information of the first sensing operation in the first node and the second node,
perform a charge sharing operation between the first node and the second node according to the sensing information of the first sensing operation during the second sensing operation, and
increase a sensing margin based on lowering a voltage level of the first node through the charge sharing operation.

2. The memory device of claim 1, wherein the plurality of memory cells includes:
a first group of memory cells that are on-cells during the first sensing operation and during the second sensing operation;
a second group of memory cells that are on-cells during the first sensing operation and are off-cells during the second sensing operation; and
a third group of memory cells that are off-cells during the first sensing operation and during the second sensing operation.

3. The memory device of claim 2,
wherein each page buffer of the plurality of page buffers is configured to
provide a first selection read voltage to a word line connected to the plurality of memory cells, the first selection read voltage being configured to cause the memory device to perform the first sensing operation, and
provide a second selection read voltage to the word line, the second selection read voltage being configured to cause the memory device to perform the second sensing operation, and
wherein the first selection read voltage has a higher voltage level than the second selection read voltage.

4. The memory device of claim 2, wherein, as part of the first sensing operation, the memory device is configured to:
precharge, during a first BL precharge operation, a first bit line connected to each memory cell of the plurality of memory cells,
precharge, during a first SO precharge operation, the first node,
connect, during a first SO develop operation, the first bit line and the first node, and
sense, during a first SO sensing operation, the first node.

5. The memory device of claim 4,
wherein each page buffer of the plurality of page buffers is configured to store, during a dump operation, a result of the first sensing operation in a sensing latch.

6. The memory device of claim 5,
wherein each page buffer of the plurality of page buffers is configured to perform the second sensing operation after the dump operation, and
wherein, as part of the second sensing operation, the page buffer is configured to:
precharge, during a second BL precharge operation, a second bit line connected to each memory cell of the plurality of memory cells,
precharge, during a second SO precharge operation, the first node,
connect, during a second SO develop operation, the second bit line and the first node,
electrically connect, during a charge sharing operation, the first node and the second node, and
sense, during a second SO sensing operation, the first node.

7. The memory device of claim 6,
wherein during the second SO precharge operation, the page buffer is configured to store the sensing information of the first sensing operation in the first node and the second node.

8. The memory device of claim 7,
wherein during the second SO precharge operation, the first group of memory cells and the second group of memory cells have a high voltage level at the first node, and the third group of memory cells has a low voltage level at the first node.

9. The memory device of claim 8,
wherein during the second SO precharge operation, the first group of memory cells and the second group of memory cells have a voltage level at the second node that corresponds to a difference between a gate voltage and a threshold voltage of the transistor, and the third group of memory cells has a ground voltage.

10. The memory device of claim 9,
wherein during the charge sharing operation, the voltage level at the first node of the third group of memory cells is decreased.

11. A memory device comprising:
a memory cell configured to store a plurality of data; and
a page buffer comprising a first node and a second node, the first node being configured to sense data stored in the memory cell, and the second node being connected to the first node through a transistor,
wherein the page buffer is configured to
store sensing information of a first sensing operation in the first node and the second node,
perform a charge sharing operation between the first node and the second node according to the sensing information of the first sensing operation during a second sensing operation, and
lower a voltage level of the first node through the charge sharing operation.

12. The memory device of claim 11,
wherein the transistor connecting the first node and the second node is an NMOS transistor.

13. The memory device of claim 11,
wherein the page buffer is configured to
provide a first selection read voltage to a selection word line connected to the memory cell, the first selection read voltage being configured to cause the memory device to perform the first sensing operation, and
provide a second selection read voltage to the selection word line, the second selection read voltage being configured to cause the memory device to perform the second sensing operation, and
wherein the first selection read voltage has a higher voltage level than the second selection read voltage.

14. The memory device of claim 11, wherein, as part of the second sensing operation, the memory device is configured to:
precharge a bit line connected to the memory cell,
precharge the first node,
connect the bit line and the first node,
charge sharing between the first node and the second node, and
sense the first node.

15. The memory device of claim 11,
wherein the memory device is a flash memory comprising a plurality of memory cells stacked in a vertical direction with respect to a substrate.

16. A sensing method of a memory device, wherein the memory device includes a memory cell storing a plurality of data and a page buffer, the page buffer comprising a first node configured to sense data stored in the memory cell and a second node connected to the first node through a transistor, the sensing method comprising:
performing a first sensing operation, the first sensing operation including a first BL precharge operation that precharges a bit line connected to the memory cell, a first SO precharge operation that precharges the first node, a first SO develop operation that connects the bit line and the first node, and a first SO sensing operation that senses the first node;
performing a dump operation that stores a result of the first sensing operation in a sensing latch; and
performing a second sensing operation, the second sensing operation including a second BL precharge operation that precharges the bit line connected to the memory cell, a second SO precharge operation that precharges the first node, a second SO develop operation that connects the bit line and the first node, a charge sharing operation that electrically connects the first node and the second node, and a second SO sensing operation that senses the first node.

17. The sensing method of claim 16, wherein the memory cell is classified into one of:
a first group of memory cells that are on-cells during the first sensing operation and during the second sensing operation;
a second group of memory cells that are on-cells during the first sensing operation and are off-cells during the second sensing operation; and
a third group of memory cells that are off-cells during the first sensing operation and during the second sensing operation.

18. The sensing method of claim 17,
wherein during the second SO precharge operation, sensing information of the first sensing operation is stored in the first node and the second node.

19. The sensing method of claim 18,
wherein during the second SO precharge operation, the first group of memory cells and the second group of memory cells have a high voltage level at the first node, and the third group of memory cells has a low voltage level at the first node.

20. The sensing method of claim 19,
wherein during the second SO precharge operation, the first group of memory cells and the second group of memory cells have a voltage level at the second node that corresponds to a difference between a gate voltage and a threshold voltage of the transistor, and the third group of memory cells has a ground voltage, and
wherein during the charge sharing operation, the voltage level at the first node of the third group of memory cells is decreased.
